(19) United States
(12) Patent Application Publication
(10) Pub. No.: US 2026/0269455 A1
(43) Pub. Date: Sep. 10, 2026

(54) ELECTRONIC DEVICE

(71) Applicant: Advanced Semiconductor Engineering, Inc., Kaohsiung (TW)

(72) Inventors: Yuanhao YU, Kaohsiung (TW); Wei Shuen KAO, Kaohsiung (TW)

(73) Assignee: Advanced Semiconductor Engineering, Inc., Kaohsiung (TW)

(21) Appl. No.: 19/074,305

(22) Filed: Mar. 7, 2025

(51) Int. Cl. H01Q 1/22; H01L 23/31; H01L 23/498; H01R 12/71

(52) U.S. Cl. CPC H01Q 1/2283; H01R 12/712; H10W 74/111; H10W 90/701

(57) ABSTRACT

The present disclosure provides an electronic device. The electronic device includes a carrier, a connector structure, and a first antenna structure. The carrier has a first surface and a second surface opposite to the first surface. The connector structure is disposed over the second surface of the carrier and defines at least one first recess configured to accommodate an external device. The first antenna structure is in directly contact with the connector structure.

### BACKGROUND

### 1. Technical Field

The present disclosure relates to an electronic device.

### 2. Description of the Related Art

Electronic devices using antennas for signal transmission (e.g., radio frequency (RF) signal) may include an antenna layer and a circuit layer electrically connected thereto. Typically, coupling members may be coupled to the feeding point and/or the grounding point of the antenna layer. However, the installation space required for these coupling members could be a bottleneck for package minimization and production efficiency. Additionally, the signal transmission through a coupling member can be unstable, potentially affecting antenna performance.

### SUMMARY

In some arrangements, an electronic device includes a carrier, a connector structure, and a first antenna structure. The carrier has a first surface and a second surface opposite to the first surface. The connector structure is disposed over the second surface of the carrier and defines at least one first recess configured to accommodate an external device. The first antenna structure is in directly contact with the connector structure.

In some arrangements, an electronic device includes a carrier, a connector structure, a first antenna structure, and a second antenna structure. The carrier has a first surface and a second surface opposite to the first surface. The connector structure is disposed over the second surface of the carrier and defines at least one first recess configured to be connected to an external device. The first antenna structure is disposed over the second surface of the carrier. The second antenna structure is disposed under the second surface of the carrier.

In some arrangements, an electronic device includes a carrier, a connector structure, and an encapsulant. The carrier has a first surface and a second surface opposite to the first surface. The connector structure is disposed over the second surface of the carrier. The connector structure includes a dielectric layer having a third surface defining a recess and a terminal within the recess. The encapsulant is disposed over the second surface of the carrier. The encapsulant has a fourth surface substantially aligned with or recessed from the third surface of the dielectric layer.

### BRIEF DESCRIPTION OF THE DRAWINGS

Aspects of some arrangements of the present disclosure are best understood from the following detailed description when read with the accompanying figures. It should be noted that various structures may not be drawn to scale, and dimensions of the various structures may be arbitrarily increased or reduced for clarity of discussion.

FIG. 1 illustrates a cross-sectional view of an electronic device, in accordance with some arrangements of the present disclosure.

FIG. 2 illustrates a cross-sectional view of an electronic device, in accordance with some arrangements of the present disclosure.

FIG. 3A illustrates a cross-sectional view of an electronic device, in accordance with some arrangements of the present disclosure.

FIG. 3B illustrates a perspective view of the electronic device as shown in FIG. 3A, in accordance with some arrangements of the present disclosure.

FIG. 4 illustrates a cross-sectional view of an electronic device, in accordance with some arrangements of the present disclosure.

FIG. 5 illustrates a cross-sectional view of an electronic device, in accordance with some arrangements of the present disclosure.

FIG. 6A illustrates one or more stages of an example of a method for manufacturing an electronic device according to some embodiments of the present disclosure.

FIG. 6B illustrates one or more stages of an example of a method for manufacturing an electronic device according to some embodiments of the present disclosure.

FIG. 6C illustrates one or more stages of an example of a method for manufacturing an electronic device according to some embodiments of the present disclosure.

FIG. 6D illustrates one or more stages of an example of a method for manufacturing an electronic device according to some embodiments of the present disclosure.

FIG. 6E illustrates one or more stages of an example of a method for manufacturing an electronic device according to some embodiments of the present disclosure.

FIG. 6F illustrates one or more stages of an example of a method for manufacturing an electronic device according to some embodiments of the present disclosure.

### DETAILED DESCRIPTION

The following disclosure provides many different arrangements, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include arrangements in which the first and second features are formed or disposed in direct contact, and may also include arrangements in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various arrangements and/or configurations discussed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of arrangements of this disclosure are not deviated from by such arrangement.

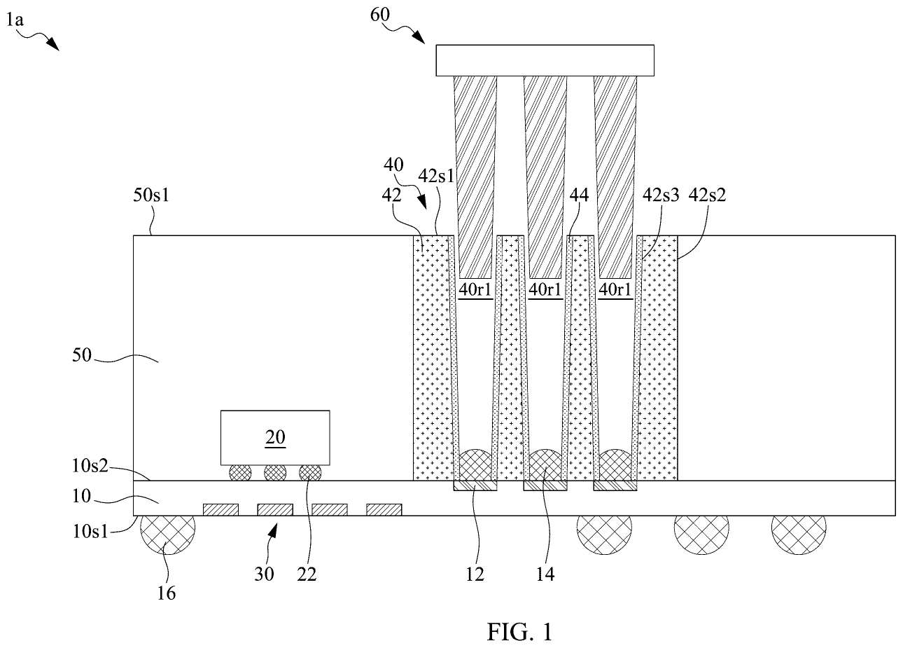

FIG. 1A illustrate an electronic device 1a in accordance with some arrangements of the present disclosure. In some arrangements, the electronic device 1a may be applicable to, for example, a wireless device, such as user equipment (UE), a mobile station, a mobile device, an apparatus communicating with the Internet of Things (IoT), etc. In some arrangements, the electronic device 1a may be or include a portable device. In some arrangements, the electronic device 1a may support fifth generation (5G) communications, such as sub-6 GHz frequency bands and/or millimeter (mm) wave frequency bands. For example, the electronic device 1a may incorporate both sub-6 GHz devices and mm wave devices. The electronic device 1a may be configured to radiate and/or receive electromagnetic signals, such as radio frequency (RF) signals. For example, the electronic device 1a may be configured to operate in a frequency between about 1 GHz and about 10 THz, such as 1 GHz, 5 GHz, 10 GHz, 20 GHz, 30 GHz, 40 GHz, 50 GHz, 100 GHz, 300 GHz, 1 THz, 5 THz, or 10 THz.

In some arrangements, the electronic device 1a may include a carrier 10, an electronic component 20, an antenna structure 30, a connector structure 40, and an encapsulant 50.

The carrier 10 may include a system board, a main board, a printed circuit board (PCB), a flexible printed circuit board (FPCB), or other suitable carriers. The carrier 10 may include a circuit structure or an interconnection structure, such as a redistribution layer (RDL), a circuit layer, a conductive trace, a conductive pad, a conductive via, etc. The carrier 10 may include a surface 10s1 (or a lower surface) and a surface 10s2 (or an upper surface) opposite to the surface 10s1. The carrier 10 may include pads 12 (or terminals) exposed by the surface 10s2. The pads 12 may be electrically connected to the connector structure 40 and/or other devices..

In some arrangements, the electronic device 1a may include electrical conductors 14. The electrical conductors 14 may be disposed on or over the surface 10s2 of the carrier 10. In some arrangements, the electrical conductors 14 may be electrically connected to the carrier 10. In some arrangements, the electrical conductors 14 may be electrically connected to the connector structure 40. In some arrangements, the electrical conductors 14 may be configured to be electrically connected to an external device 60. In some arrangements, the electrical conductors 14 may include a reflowable material or a solder material, such as tin (Sn), gallium (Ga), indium (In), bismuth (Bi), or other suitable materials.

The electronic device 1a may include electrical conductors 16 (or electrical connections). The electrical conductors 16 may be disposed on or under the surface 10s1 of the carrier 10. In some arrangements, the electrical conductors 16 may be electrically connected to an external device (e.g., a circuit board). In some arrangements, the electrical conductors 16 may include a reflowable material or a solder material, such as tin (Sn), gallium (Ga), indium (In), bismuth (Bi), or other suitable materials.

In some arrangements, the electronic component 20 may be disposed on or over the surface 10s2 of the carrier 10. In some arrangements, the electronic component 20 may be configured to control the antenna elements (e.g., antenna structure 30). For example, the electronic component 20 may be configured to control the feeding start and end times, the feeding duration, the number of feed points, the location of feed points, the RF impedance matching, the transmitting start and end times, the receiving start and end times, the grounding start and end times, the grounding duration, the number of ground points, the location of ground points, the frequencies (or operating frequencies), the bandwidths (or operating bandwidths), the wavelengths of the EM waves, etc.

The electronic component 20 may be a chip or a die including a semiconductor substrate, one or more integrated circuit devices and one or more overlying interconnection structures therein. The integrated circuit devices may include active devices such as transistors and/or passive devices such as resistors, capacitors, inductors, or a combination thereof. In some arrangements, the electronic component 20 may include a transmitter, a receiver, or a transceiver. In some arrangements, the electronic component 20 may include a processing unit and/or a controller. In some arrangements, the electronic component 20 may include a radio frequency IC (RFIC), an analog-to-digital (A/D) converter, a digital-to-analog (D/A) converter, a filter, a low noise amplifier (LNA), a power amplifier, a multiplexer, a demultiplexer, a modulator, and/or a demodulator, etc. Although FIG. 1 illustrates that the electronic device 1a includes one electronic component 20, it should be noted that the electronic device 1a may include more electronic components based on the requirements.

The electronic component 20 may be electrically connected to the carrier 10 by electrical conductors 22. In some arrangements, the electrical conductors 22 may include a reflowable material or a solder material, such as tin (Sn), gallium (Ga), indium (In), bismuth (Bi), or other suitable materials. For example, the electrical conductors 22 may include a solder ball, such as a controlled collapse chip connection (C4) bump, a ball grid array (BGA), a land grid array (LGA), or so on. In other arrangements, the electronic component 20 may be electrically connected to the carrier 10 by a conductive wire (or bonding wire) or other suitable elements.

In some arrangements, the antenna structure 30 may abut the surface 10s1 of the carrier 10. The antenna structure 30 may be exposed by the surface 10s1 of the carrier 10. In some arrangements, the antenna structure 30 may perform short-range communication with, e.g., an external device or may wirelessly transmit or receive power necessary for charging. In some arrangements, the antenna structure 30 may be configured to radiate and/or receive electromagnetic (EM) signals, such as RF signals. In some arrangements, the antenna structure 30 may include an antenna in package (AiP) device or an antenna on package (AoP) device. In some arrangements, the antenna structure 30 may be electrically connected to the electronic component 20 through the carrier 10. The antenna structure 30 may be of any suitable type, such as patch antennas, slot-coupled antennas, stacked patches, dipoles, monopoles, etc., and may have different orientations and/or polarizations. The antenna structure 30 may include an ultra-wideband antenna. In simulated results of reflection coefficient versus frequency of the antenna structure 30, the range/band of frequencies less than 10% of the fed signal (i.e., 10 dB) is between approximately 50 GHz and 100 GHz, such as 50 GHz, 60 GHz, 70 GHz, 80 GHz, 90 GHz, or 100 GHz.

In some arrangements, the connector structure 40 may be disposed on or over the surface 10s2 of the carrier 10. In some arrangements, a portion of the surface 10s2 of the carrier 10 may be exposed by the connector structure 40. In some arrangements, the connector structure 40 may be electrically connected to the carrier 10. In some arrangements, the connector structure 40 may be configured to connect an external device 60 and the carrier 10. In some arrangements, the connector structure 40 may function as a socket configured to be connected to the external device 60 which has pins or plugs. In some arrangements, the connector structure 40 may define a plurality of recesses 40r1 (or openings or through holes) for accommodating the external device 60. In some arrangements, the electrical conductors 14 may be disposed within the recesses 40r1 of the connector structure 40. In some arrangements, the connector structure 40 may include a dielectric structure 42 and conductive elements 44. The recess 40r1 may be tapered toward the carrier 10. In some arrangements, the recess 40r1 may vertically overlap the electrical conductor 16.

The dielectric structure 42 (or dielectric layer) may be disposed on or over the surface 10s2 of the carrier 10. In some arrangements, the dielectric structure 42 may have a relatively high glass transition temperature (Tg) or melting point. For example, the Tg or the melting point of the dielectric structure 42 may be greater than that of the acrylonitrile butadiene styrene (ABS) substrate. In some arrangements, the Tg or the melting point of the dielectric structure 42 may be greater than 100° C., such as 100° C., 110° C., 130° C., 150° C., 200° C., 220° C., 240° C., 260° C., 280° C., 300° C., or more. In some arrangements, the dielectric structure 42 may include a polymer. For example, the dielectric structure 42 may include a thermoplastic material (e.g., polycarbonate or other suitable materials). The dielectric structure 42 may include additives, such as a metallic inorganic material or other suitable materials. The dielectric structure 42 may have a dielectric constant (Dk) between about 2 and 6. The dielectric structure 42 may have a dissipation factor (Df) between about 0 and 0.009. The dielectric structure 42 may include a surface 42s1 (or an upper surface), surfaces 42s2 (or outer lateral surfaces or outer lateral sidewalls), and surfaces 42s3 (or inner lateral surfaces or inner lateral sidewalls). In some arrangements, the surface 42s3 may define the recesses 40r1 that extend between the surface 10s2 of the carrier 10 and the surface 42s1 of the dielectric structure 42. In some arrangements, the slope defined by the surface 42s2 and the normal direction of the surface 10s2 may be different from the slope defined by the surface 42s3 and the normal direction of the surface 10s2. In some arrangements, the surface 42s2 may be steeper than the surface 42s3. In some arrangements, the surface 42s2 of the dielectric structure 42 may be substantially orthogonal to the surface 10s2 of the carrier 10. In some arrangements, the surface 42s3 of the dielectric structure 42 may be slanted with respect to the surface 10s2 of the carrier 10.

In some arrangements, the conductive elements 44 (or terminals) may be pre-formed by a laser direct structuring (LDS) process. In some arrangements, the conductive element 44 may be supported by the dielectric structure 42. In some arrangements, the conductive element 44 may be disposed on the surface 42s3 of the dielectric structure 42. In some arrangements, the conductive element 44 may be disposed within the recesses 40r1. In some arrangements, the conductive element 44 may extend between the surface 42s1 of the dielectric structure 42 and the surface 10s2 of the carrier 10. In some arrangements, the conductive element 44 may be configured to be electrically connected to the carrier 10. In some arrangements, the conductive element 44 may be configured to be electrically connected to the external device 60. In some arrangements, the conductive element 44 may be configured to be electrically connected to the electrical conductor 14. In some arrangements, the conductive element 44 may include copper (Cu), aluminum (Al), tin (Sn), gold (Au), silver (Ag), nickel (Ni), or stainless steel, or a mixture, an alloy, or other combination thereof.

In some arrangements, the encapsulant 50 may be disposed on or over the surface 10s2 of the carrier 10. In some arrangements, the encapsulant 50 may encapsulate the electronic component 20. In some arrangements, the encapsulant 50 may encapsulate the connector structure 40. The encapsulant 50 may have a surface 50s1 (or an upper surface). In some arrangements, the surface 50s1 may be substantially aligned with the surface 42s1 of the dielectric structure 42. In some arrangements, the encapsulant 50 may be in contact with the surface 42s2 of the dielectric structure 42. In some arrangements, the encapsulant 50 may be spaced apart from the surface 42s3 of the dielectric structure 42. In some arrangements, the connector structure 40 may be exposed by the surface 50s1 of the encapsulant 50. In some arrangements, the encapsulant 50 may surround the connector structure 40. In some arrangements, the encapsulant 50 may be made of molding material that may include, for example, a novolac-based resin, an epoxy-based resin, a silicone-based resin, or another suitable encapsulant. Suitable fillers may also be included, such as powdered SiO₂. In some arrangements, the encapsulant 50 may include a molding compound, which is formed by a molding technique, such as compression molding, injection molding, or transfer molding.

In some cases, an electronic device is electrically connected to an external device. A connector can be used to conform the profile of the external device. The connector may be mounted onto a carrier using surface mount technology (SMT), followed by a reflow process to secure the connector to the carrier. In this scenario, if the dielectric material of the connector has a relatively low glass transition temperature or melting point (e.g., less than 200° C.), it may become deformed during the reflow process, which typically occurs at temperatures exceeding 200° C. In some arrangements, the Tg or melting point of the dielectric structure 42 of the connector structure 40 is greater than 200° C. or more. Consequently, the connector structure 40 remains free from deformation after the reflow process. As a result, the electronic device 1a can offer more flexible connections to external devices, making it suitable for SMT without degrading the connector structure 40.

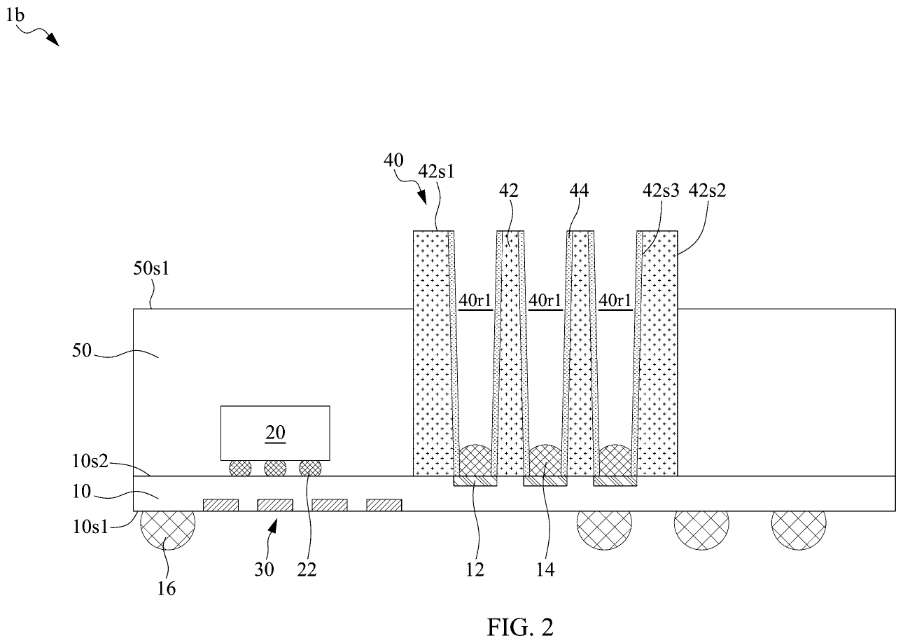

FIG. 2 illustrates a cross-sectional view of an electronic device 1b, in accordance with some arrangements of the present disclosure. The electronic device 1b is similar to the electronic device 1a, differing as follows.

In some arrangements, a portion of the encapsulant 50 may be removed. In some arrangements, the surface 50s1 of the encapsulant 50 may not be aligned with the surface 42s1 of the dielectric structure 42. In some arrangements, a portion of the connector structure 40 may be protruded from the surface 50s1 of the encapsulant 50. The surface 50s1 of the encapsulant 50 may be at a level (or height or elevation) lower than the that of surface 42s1 of the dielectric structure 42 with respect to the surface 10s2 of the carrier 10. In some arrangements, a portion of the surface 42s2 of the dielectric structure 42 may be exposed by the encapsulant 50. In this arrangement, the design of the encapsulant 50 may be configured to conform the profile of an external device. For example, when an external device has a dielectric part encapsulating pins, the exposed surface 42s2 of the dielectric structure 42 may be configured to conform the profile of the dielectric part of the external device.

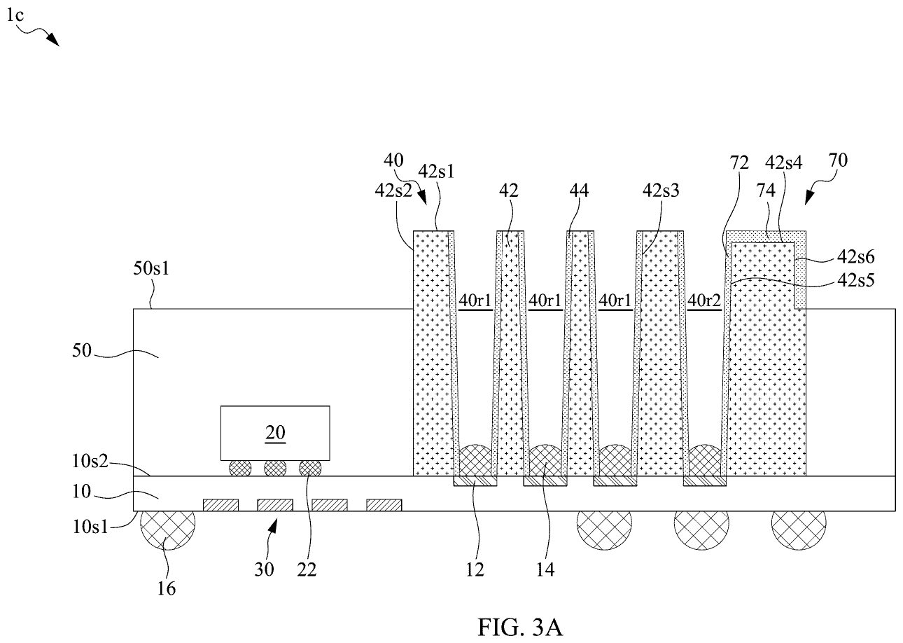

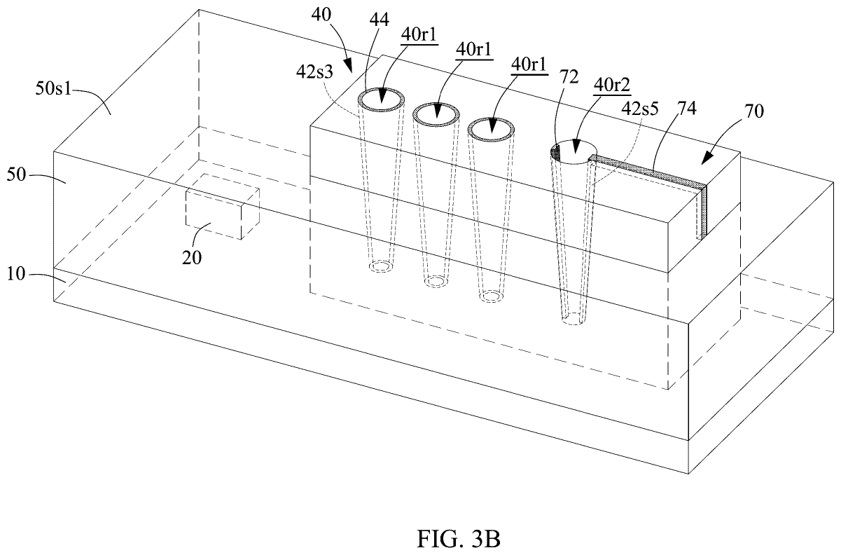

FIG. 3A and FIG. 3B illustrate an electronic device 1c, in accordance with some arrangements of the present disclosure. The electronic device 1c is similar to the electronic device 1b, differing as follows.

In some arrangements, the electronic device 1c may include an antenna structure 70. As shown in FIG. 3A, the antenna structure 70 may be disposed on or over the surface 10s2 of the carrier 10. In some arrangements, the antenna structure 70 may be integrated with the connector structure 40. In some arrangements, the antenna structure 70 may be in directly contact with the connector structure 40. In some arrangements, the antenna structure 70 may be partially embedded within the connector structure 40. In some arrangements, the antenna structure 70 may be pre-formed by a laser direct structuring process. In some arrangements, the antenna structure 70 may be supported by the connector structure 40. In some arrangements, the antenna structure 70 may be electrically connected to the electronic component 20 through the carrier 10. In some arrangements, the antenna structure 70 may perform short-range communication with, e.g., an external device or may wirelessly transmit or receive power necessary for charging. In some arrangements, the antenna structure 70 may be configured to radiate and/or receive electromagnetic signals, such as RF signals. The antenna structure 70 may be of any suitable type, such as patch antennas, slot-coupled antennas, stacked patches, dipoles, monopoles, etc., and may have different orientations and/or polarizations. The antenna structure 70 may include an ultra-wideband antenna. In some arrangements, the antenna structure 70 and connector structure 40 may operate at different frequencies. For example, in simulated results of reflection coefficient versus frequency of the antenna structure 70, the range/band of frequencies less than 10% of the fed signal (i.e., 10 dB) is between approximately 1 GHz and 50 GHz, such as 1 GHz, 3 GHz, 5 GHz, 10 GHz, 30 GHz, or 50 GHz. The antenna structure 70 may include a feeding element 72 and a pattern 74.

In some arrangements, the connector structure 40 may have a surface 42s4 (or an upper surface) and a surface 42s5 (or a lateral surface). The surface 42s4 may be configured to support the pattern 74 (or antenna pattern) of the antenna structure 70. In some arrangements, the surface 42s4 may be at a level (or an elevation or a height) lower than that of the surface 42s1 with respect to the carrier 10. The surface 42s5 may be configured to support, for example, the feed line of the antenna structure 70. The surface 42s5 of the dielectric structure 42 may define a recess 40r2 for accommodating the feeding element 72 of the antenna structure 70. The feeding element 72 of the antenna structure 70 may penetrate the dielectric structure 42. The recess 40r2 may be configured to accommodate the electrical conductor 14. A portion of the antenna structure 70 may be exposed from a surface 42s6 (or a lateral surface) of the dielectric structure 42. In some arrangements, the antenna structure 70 may be exposed by the encapsulant 50. In some arrangements, the antenna structure 70 may be laterally spaced apart from the antenna structure 30 by the connector structure 40. In some arrangements, the antenna structure 70 may be laterally spaced apart from the antenna structure 30 by the recesses 40r1. In some arrangements, the recess 40r2 may vertically overlap the electrical conductor 16.

The feeding element 72 may be configured to transmit a feeding signal. The feeding element 72 may be supported by the surface 42s5. In some arrangements, the feeding element 72 may extend between the pattern 74 and the surface 10s2 of the carrier 10. The material of the feeding element 72 may be different from that of the electrical conductors 14. In some arrangements, the feeding element 72 may be at a level substantially the same as that of the conductive element 44. In some arrangements, the feeding element 72 may laterally overlap the conductive element 44. The feeding element 72 may include copper (Cu), aluminum (Al), tin (Sn), gold (Au), silver (Ag), nickel (Ni), or stainless steel, or a mixture, an alloy, or other combination thereof.

In some arrangements, the pattern 74 may be disposed adjacent to the surface 42s4 of the dielectric structure 42. In some arrangements, the pattern 74 may be supported by the dielectric structure 42. The pattern 74 may be configured to receive and/or transmit an RF signal from and/or toward the environment. Further, the profile of the pattern 74 as shown in FIGS. 3A and 3B is merely exemplary; the pattern 74 may include other shapes, such as a circle, an oval, a triangle, a quadrangle, a polygon, or a combination thereof. The pattern 74 may be exposed by the connector structure 40. The pattern 74 may be exposed by the encapsulant 50.

As shown in FIG. 3B, the connector structure 40 may be surrounded by the encapsulant 50. In some arrangements, the conductive element 44 may substantially completely cover the surface 42s3 which defines the recesses 40r1. In some arrangements, a portion of the surface 42s5, which defines the recess 40r2, may be exposed by the feeding element 72. For example, a portion of the surface 42s5 may be exposed to air. It should be noted that the profile of the antenna structure 70 is for illustrative purposes only and may be modified according to design requirements.

In this arrangements, the antenna structure 70 may be integrated with or supported by the connector structure 40. The surface 10s2 of the carrier 10 may be configured not only to receive and/or emit RF signals but also to connect to an external device. This capability helps reduce the dimensions of the electronic device 1c and offers greater flexibility in design layout.

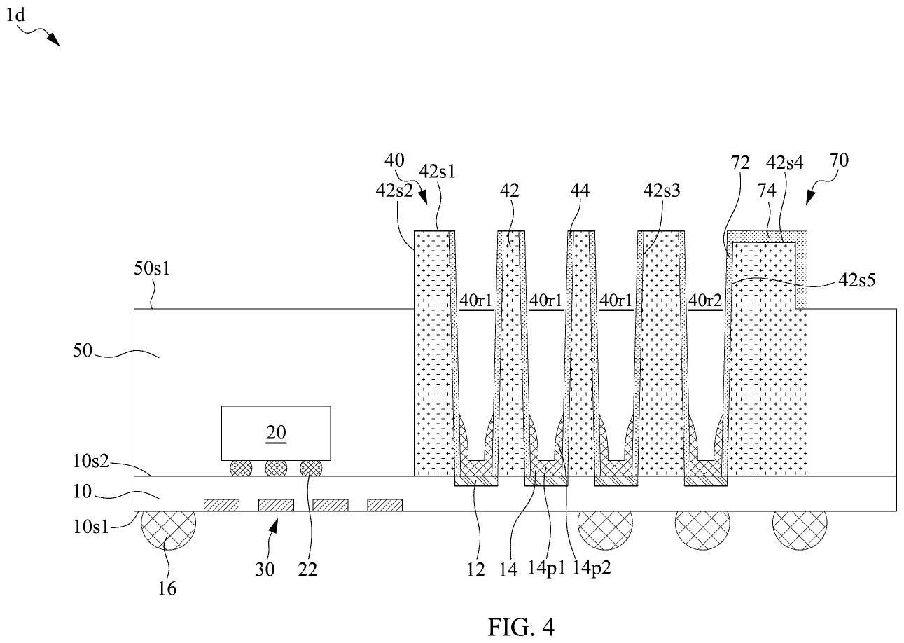

FIG. 4 illustrates a cross-sectional view of an electronic device 1d, in accordance with some arrangements of the present disclosure. The electronic device 1d is similar to the electronic device 1c, differing as follows.

In some arrangements, the electrical conductors 14 may include a base portion 14p1 and an extending portion 14p2. The base portion 14p1 may be disposed on or over the pads 12. The extending portion 14p2 may protrude from the base portion 14p1 and toward the antenna structure 70. In some arrangements, when the reflowable temperature (may be about 260 degrees Celsius or higher) of the electrical conductor 14 is reached, the electrical conductor 14 can be softened, liquefied, or become flowable and may climb/flow onto the conductive element 44 or onto the feeding element 72.

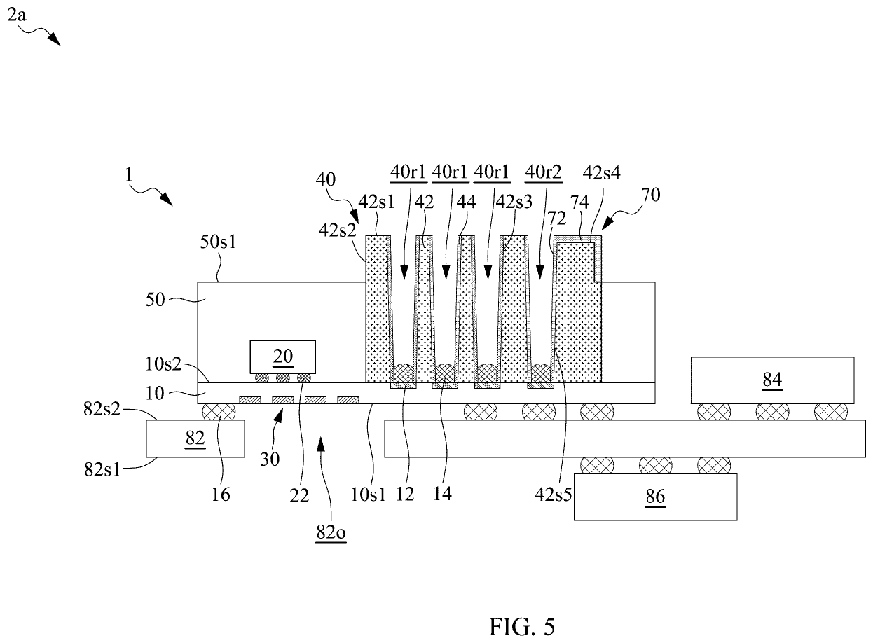

FIG. 5 illustrates a cross-sectional view of an electronic device 2a, in accordance with some arrangements of the present disclosure. The electronic device 2a is similar to the electronic device 1c, differing as follows.

In some arrangements, the electronic device 2a may include a circuit structure 82. The circuit structure 82 may include a system board, a main board, a printed circuit board (PCB), a flexible printed circuit board (FPCB), or other suitable carriers. The circuit structure 82 may include a circuit structure or an interconnection structure, such as a redistribution layer (RDL), a circuit layer, a conductive trace, a conductive pad, a conductive via, etc. The circuit structure 82 may include a surface 82s1 (or a lower surface) and a surface 82s2 (or an upper surface) opposite to the surface 82s1.

In some arrangements, the electronic device 2a may include an electronic structure 1. The electronic structure 1 may include a structure the same as or similar to that of the electronic devices 1a to 1d. The electronic structure 1 may be disposed on or over the surface 82s2 of the circuit structure 82. In some arrangements, the electronic structure 1 may be electrically connected to the circuit structure 82 through the electrical conductors 16. In some arrangements, the circuit structure 82 may define an opening 82o exposing the antenna structure 30. In some arrangements, the electronic component 20 may vertically overlap the opening 82o of the circuit structure 82. In some arrangements, a portion of the connector structure 40 may vertically overlap the opening 82o of the circuit structure 82.

In some arrangements, the electronic device 2a may include an electronic component 84. The electronic component 84 may be disposed on or over the surface 82s2 of the circuit structure 82. In some arrangements, the electronic component 84 may include a chip or a die or a package integrating multiple dies. In some arrangements, the electronic component 84 may include an application-specific IC (ASIC), a central processing unit (CPU), a microprocessor unit (MPU), a graphics processing unit (GPU), a microcontroller unit (MCU), a field-programmable gate array (FPGA), a power management IC (PMIC), power module, or another type of IC. In some embodiments, the electronic component 84 may include an analog to digital converter, a digital to analog converter, a switch, a mixer, a low noise amplifier (LNA), a transceiver, power monitor, and/or other integrated circuits. In some arrangements, the electronic component 84 may laterally overlap the electronic structure 1. In some arrangements, the electronic component 84 may laterally overlap the carrier 10. In some arrangements, the electronic component 84 may laterally overlap the encapsulant 50. In some arrangements, the electronic component 84 may be disposed outside the encapsulant 50. The electronic component 84 may be electrically connected to the electronic structure 1 through the circuit structure 82. In some arrangements, the electronic component 84 may laterally overlap the connector structure 40.

In some arrangements, the electronic device 2a may include an electronic component 86. The electronic component 86 may be disposed on or under the surface 82s1 of the circuit structure 82. In some arrangements, the electronic component 86 may include a chip or a die or a package integrating multiple dies. In some arrangements, the electronic component 86 may include an application-specific IC (ASIC), a central processing unit (CPU), a microprocessor unit (MPU), a graphics processing unit (GPU), a microcontroller unit (MCU), a field-programmable gate array (FPGA), a power management IC (PMIC), power module, or another type of IC. In some embodiments, the electronic component 86 may include an analog to digital converter, a digital to analog converter, a switch, a mixer, a low noise amplifier (LNA), a transceiver, power monitor, and/or other integrated circuits. The electronic component 86 may be electrically connected to the electronic structure 1 through the circuit structure 82.

In a comparative example, the antenna, corresponding to the antenna structure 70 of the electronic device 2a, may be formed on the circuit structure 82, which may occupy an additional area. In this arrangement, the antenna structure 70 may be integrated with the electronic structure 1, which may reduce the overall dimension of the electronic device 2a. In this arrangement, the significant difference in operating frequencies between antenna structure 30 and antenna structure 70 may help prevent crosstalk issues.

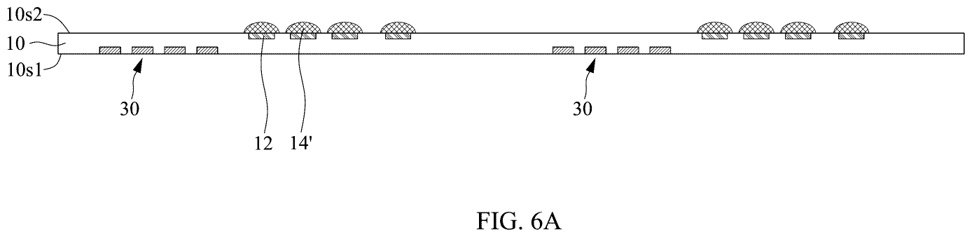

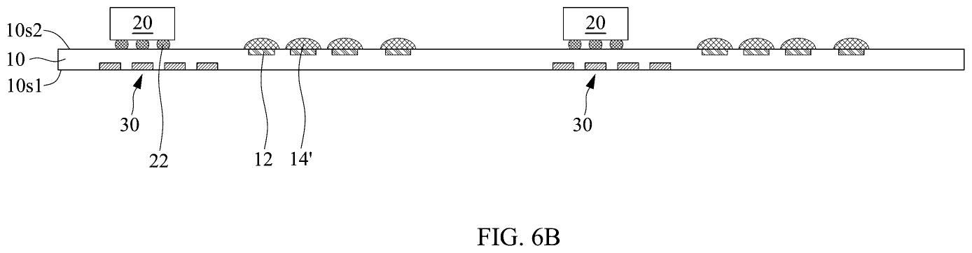

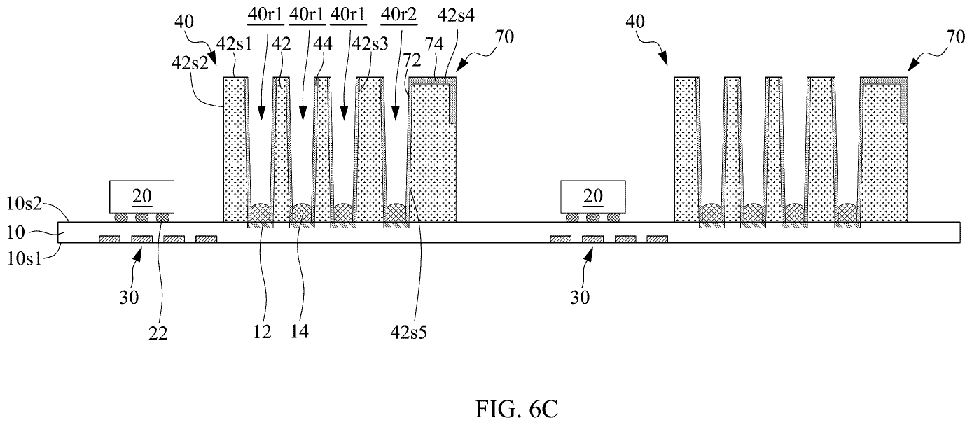

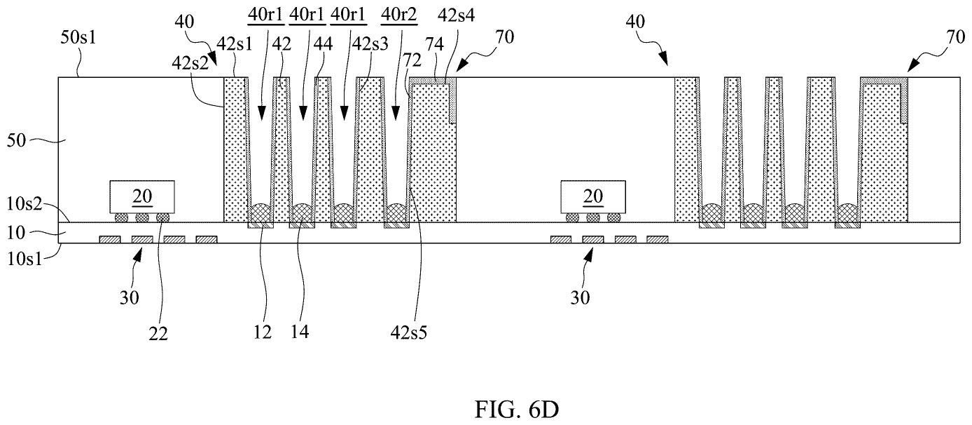

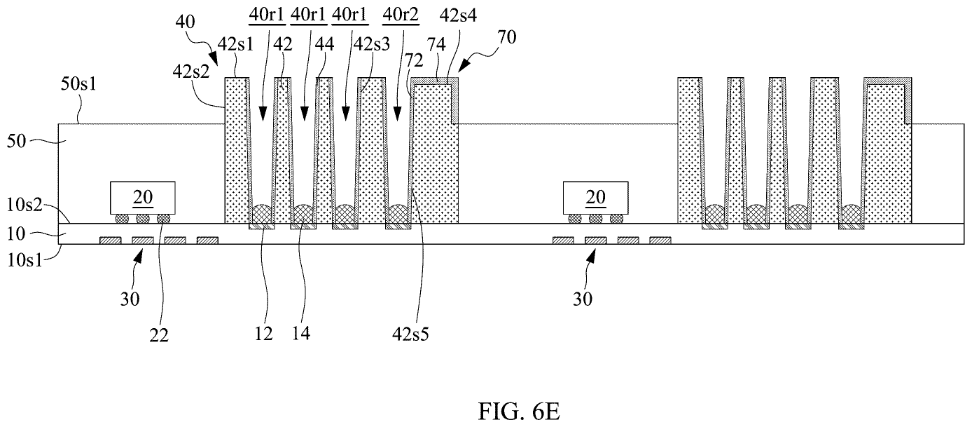

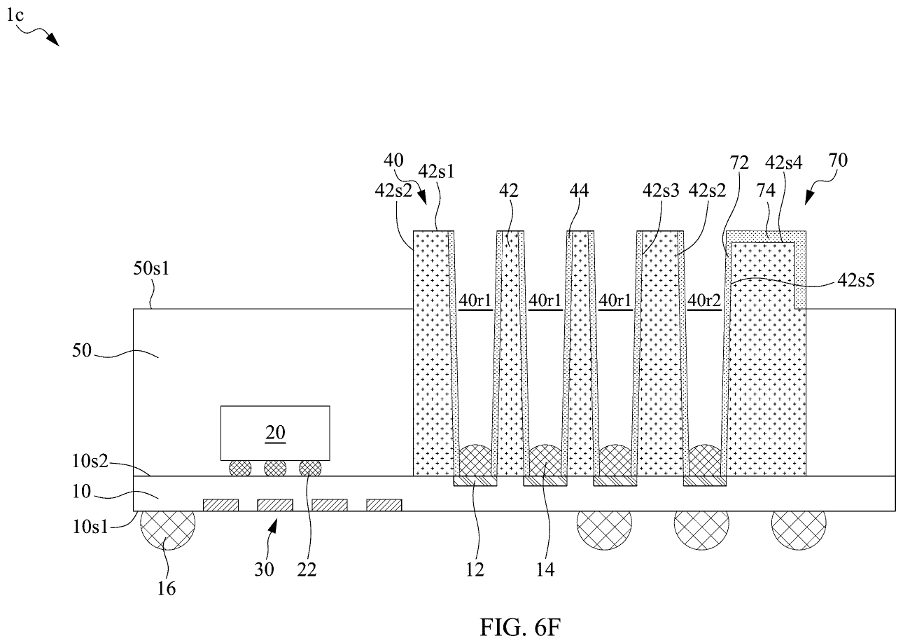

FIGS. 6A to 6F illustrate various stages of an example of a method for manufacturing an electronic device according to some embodiments of the present disclosure.

Referring to FIG. 6A, the carrier 10, including a plurality of repeated units, may be provided. The units may be separated from each other after a singulation technique is performed. The antenna structure 30 may be formed abutting the surface 10s1 of the carrier 10. A reflowable material 14′ may be formed on or over the surface 10s2 of the carrier 10 by, for example, a printing technique or other suitable techniques.

Referring to FIG. 6B, the electronic component 20 may be formed on or over the surface 10s2 of the carrier 10.

Referring to FIG. 6C, the connector structure 40 integrated with the antenna structure 70 may be formed on or over the surface 10s2 of the carrier 10. The connector structure 40 may be mounted onto the carrier 10 using surface mount technology. In some arrangements, the recesses 40r1 and recess 40r2 may be aligned with the reflowable material 14′, and a reflow process may be performed to connect the connector structure 40 and the carrier 10 and connect the antenna structure 70 and the carrier 10. In some arrangements, the reflow process may be performed at a temperature greater than 200° C. (e.g., 260° C.). In this arrangement, the Tg or melting point of the dielectric structure 42 of the connector structure 40 is greater than 200° C. or more. Consequently, the connector structure 40 remains free from deformation after the reflow process.

Referring to FIG. 6D, the encapsulant 50 may be formed on or over the surface 10s2 of the carrier 10. The encapsulant 50 may be formed by a molding technique, such as compression molding, injection molding, or transfer molding.

Referring to FIG. 6E, a portion of the encapsulant 50 may be removed. As a result, a portion of the connector structure 40 may be protruded from the surface 50s1 of the encapsulant 50. In some arrangements, a removing technique (e.g., laser drilling) may be performed to remove a portion of the encapsulant 50. In some arrangements, a smoothing technique (e.g., laser polish) may be performed to smooth the surface 50s1 of the encapsulant 50.

Referring to FIG. 6F, the repeated units may be separated by a singulation technique, and the electrical conductors 16 may be formed on or under the surface 10s1 of the carrier 10. An electronic device (e.g., the electronic device 1c) may be produced.

As used herein, the singular terms “a,” “an,” and “the” may include a plurality of referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0°that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific arrangements thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a carrier having a first surface and a second surface opposite to the first surface;
a connector structure disposed over the second surface of the carrier and defining at least one first recess configured to accommodate an external device; and
a first antenna structure in directly contact with the connector structure.

2. The electronic device of claim 1, wherein the connector structure defines a second recess accommodating a portion of the first antenna structure.

3. The electronic device of claim 1, further comprising:
a reflowable material disposed within the at least one first recess.

4. The electronic device of claim 1, further comprising:
a second antenna structure disposed under the second surface of the carrier.

5. The electronic device of claim 4, wherein an operating frequency of the first antenna structure is different from that of the second antenna structure.

6. The electronic device of claim 1, further comprising:
an encapsulant encapsulating the connector structure.

7. The electronic device of claim 6, wherein a portion of the connector structure is protruded from the encapsulant.

8. The electronic device of claim 6 wherein the first antenna structure is at a level higher than a level of a surface, spaced apart from the carrier, of the encapsulant with respect to the second surface of the carrier.

9. The electronic device of claim 2, further comprising:
a circuit structure supporting the carrier and one second recess of the carrier.

10. An electrical connection between the carrier and the circuit structure, wherein the electrical
connection vertically overlaps the at least one second recess of the carrier. An electronic device, comprising:
a carrier having a first surface and a second surface opposite to the first surface;
a connector structure disposed over the second surface of the carrier and defining at least one recess configured to accommodate an external device;
a first antenna structure disposed over the second surface of the carrier; and
a second antenna structure disposed under the second surface of the carrier.

11. The electronic device of claim 10, wherein the first antenna structure is supported by the connector structure.

12. The electronic device of claim 10, wherein the connector structure comprises a dielectric layer having a third surface from which the at least one recess is recessed and a fourth surface supporting the first antenna structure, and an elevation, with respect to the second surface of the carrier, of the third surface is different from that of the fourth surface.

13. The electronic device of claim 10, further comprising:
an encapsulant surrounding the connector structure.

14. The electronic device of claim 13, wherein the connector structure has a third surface from which the at least one recess is recessed, and the encapsulant has a surface substantially aligned with the third surface of the connector structure.

15. The electronic device of claim 13, wherein the connector structure has a third surface from which the at least one recess is recessed, and the encapsulant has a surface recessed from the third surface of the connector structure.

16. The electronic device of claim 10, wherein the first antenna structure is laterally spaced apart from the second antenna structure by the at least one recess.

17. An electronic device, comprising:
a carrier having a first surface and a second surface opposite to the first surface;
a connector structure disposed over the second surface of the carrier, wherein the connector structure comprises:
a dielectric layer having a third surface defining a recess; and
a terminal within the recess; and
an encapsulant disposed over the second surface of the carrier, wherein the encapsulant has a fourth surface substantially aligned with or recessed from the third surface of the dielectric layer.

18. The electronic device of claim 17, further comprising:
a first antenna structure supported by the dielectric layer of the connector structure.

19. The electronic device of claim 18, further comprising:
a second antenna structure exposed by the first surface of the carrier.

20. The electronic device of claim 19, further comprising:
a circuit structure supporting the carrier and defining an opening exposing the second antenna structure.
